(19) United States
(12) Patent Application Publication
(10) Pub. No.: US 2026/0123128 A1
(43) Pub. Date: Apr. 30, 2026

(54) MASK-FREE PRINTABLE ALTERNATING-CURRENT ELECTROLUMINESCENT FILM

(71) Applicant: Purdue Research Foundation, West Lafayette, IN (US)

(72) Inventors: Chi Hwan Lee, West Lafayette, IN (US); Tianhao Yu, West Lafayette, IN (US)

(73) Assignee: Purdue Research Foundation, West Lafayette, IN (US)

(21) Appl. No.: 19/375,742

(22) Filed: Oct. 31, 2025

Related U.S. Application Data
(60) Provisional application No. 63/714,844, filed on Oct. 31, 2024.

(51) Int. Cl. H10H 29/14; H10H 29/01; H10H 29/851

(52) U.S. Cl. CPC H10H 29/142; H10H 29/011; H10H 29/032; H10H 29/8512

(57) ABSTRACT

A stretchable and flexible electroluminescent film may include a bottom substrate layer and a bottom electrode layer on the substrate layer. A dielectric layer may be included on the bottom electrode layer. An electroluminescent layer may be included on the dielectric layer. The electroluminescent layer may illuminate in response to an electric field. The film may further include a top electrode layer configured to provide the electromagnetic field with the bottom electrode layer. The film may further include a top substrate layer on the electrode layer. The bottom substrate layer, the bottom electrode layer, the dielectric layer and the electroluminescent layer each include an elastomeric polymer. The film may be printer layer by layer using a mask-free additive manufacturing process.

### CROSS REFERENCE TO RELATED APPLICATIONS

This application claims the benefit of U.S. Provisional Application No. 63/714,844, filed on Oct. 31, 2024, the entire contents of which are hereby incorporated by reference in their entirety.

### TECHNICAL FIELD

This disclosure relates to electroluminescent devices and, in particular, to alternating-current electroluminescent devices.

### BACKGROUND

Electroluminescent (EL) devices have garnered significant attention for their potential in flexible displays, wearable electronics, and soft robotics due to their mechanical flexibility, robustness, and ability to emit light under alternating current (AC) activation. Conventional fabrication methods for EL devices—such as thermal lamination, transfer printing, and screen printing—are often labor-intensive, require multiple processing steps, and depend on the use of masks, which complicate alignment and limit scalability.

These traditional approaches also suffer from limitations in design flexibility and precision, making them less suitable for advanced applications that demand high-resolution patterning and mechanical durability. Moreover, the reliance on UV-curable elastomers introduces challenges such as material degradation and the need for specialized curing equipment.

### BRIEF DESCRIPTION OF THE DRAWINGS

The embodiments may be better understood with reference to the following drawings and description. The components in the figures are not necessarily to scale. Moreover, in the figures, like-referenced numerals designate corresponding parts throughout the different views.

FIG. 1 illustrates a schematic diagram of a printable alternating-current electroluminescent film manufactured using an additive manufacturing system.

FIG. 2 illustrates an example of an electroluminescent device providing a multiplexed display.

FIG. 3 presents the chromaticity coordinates of the blue, green, and orange emissions for achieved by various examples of the electroluminescent film described herein.

FIG. 4A-B illustrates charts showing the viscosity and light emission characteristics of the electroluminescent layer according to some examples described herein.

FIG. 5A-D illustrates charts showing the electrical and mechanical characterization the electroluminescent film according to some examples described herein.

FIG. 6A-D illustrates charts showing the light emission characteristics of the electroluminescent film a according to some examples described herein.

### DETAILED DESCRIPTION

Alternating-current electroluminescent (ACEL) devices are distinguished by their simplicity, mechanical flexibility, and robustness, as they use AC voltage to activate luminescent materials embedded in elastomers. These properties make ACEL devices ideal for a range of electronic applications, including flexible displays, wearable electronics, and soft robotics. Recent efforts in ACEL device development have focused on improving their durability and stretchability to meet the demands of increasingly dynamic and flexible environments. Traditionally, fabrication has relied on various techniques, such as thermal lamination, transfer printing, and especially screen printing. While these methods have been essential to the progress of ACEL devices, they often require multiple steps and specialized equipment, such as masks, which complicates the process. Issues like mask alignment between layers lead to inconsistencies, limiting scalability and adaptability. Additionally, these methods frequently lack the precision required for more advanced applications, highlighting the need for more efficient and accessible fabrication techniques.

To address these challenges, this disclosure provides a layer-by-layer direct-write printing strategy for creating a mask-free, fully printable alternating-current electroluminescent film. Unlike other existing printing techniques, the electroluminescent film and method of manufacture described herein eliminates the need for masks. By utilizing a commercial dispenser system for the precise deposition of solution-based materials, it simplifies the fabrication process, enhances design flexibility, and resolves mask alignment issues, resulting in more consistent and reliable production. Although direct-write methods have been explored previously, use of an elastomeric polymer, such as thermoplastic polyurethane (TPU), enables the production of a thinner, more stretchable EL film.

An example of the technical advancements provided by the EL film, and related methods of manufacture, is a new approach to printing multicolor EL films for flexible displays using a commercial dispenser system. Unlike traditional printing methods including screen printing, the refined technique described herein is well-suited for creating custom designs. It offers precise control over the printing process, allowing for the development of intricate patterns and high-resolution displays that are difficult to achieve with conventional methods. The method disclosed herein supports high-density pixel printing while maintaining consistent luminescence, with relative deviations of less than 10%. This uniformity in brightness is crucial for display applications that require high precision and clarity. Additionally, the printed films exhibit outstanding durability, enduring over 10,000 folding cycles without any significant loss in performance. The films also maintain their functionality up to 180% elongation, making them ideal for wearable electronics and other applications that require flexibility under mechanical strain.

The versatility of these printed EL films is further enhanced by their adjustable colors and luminescent intensities, enabling the creation of displays with a wide range of color outputs suitable for different environmental conditions and user preferences. The use of programmable pixels adds another layer of flexibility, allowing for dynamic and interactive displays that can be tailored to specific applications such as real-time data visualization and interactive user interfaces.

The effectiveness of the electroluminescent film and related methods of manufacture is demonstrated through the creation of complex EL patterns and a flexible matrix within a small area (e.g. 2×2 cm²), capable of displaying alphanumeric characters and other symbols. The film exhibits consistent luminescence with minimal intensity variation, robust durability through extensive mechanical deformation, and high flexibility. For example, the film can be stretched up to 180% of their original length and withstand 10,000 bending/stretching cycles without significant loss of luminance. This disclosure introduces a transformative, fully printable fabrication strategy for flexible EL devices, paving the way for the development of advanced stretchable displays and a range of other innovative applications. By addressing the limitations of traditional printing techniques and leveraging the unique advantages of a mask-free, direct-write printing process, our work advances stretchable EL devices and opens new possibilities for their use in cutting-edge technologies.

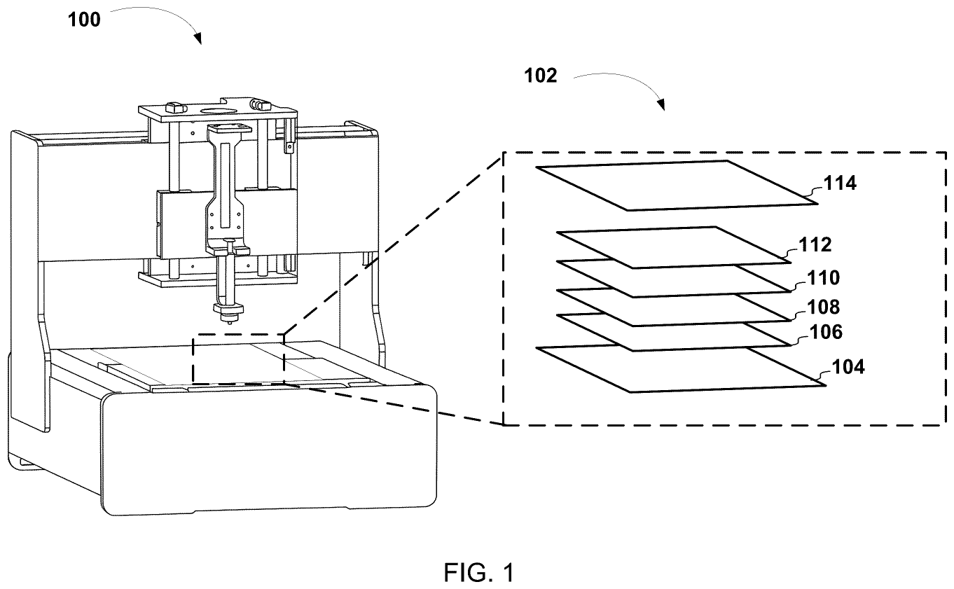

FIG. 1 illustrates a schematic diagram of a printable alternating-current electroluminescent film 100 manufactured using an additive manufacturing system 102. The additive manufacturing system 102 may utilize direct-write printing to deposit functional materials in a layer-by-layer fashion, eliminating the need for complex photolithography or masking steps, thereby simplifying the manufacturing process and reducing costs. Compared to other methods, this approach allows for the creation of highly customizable and intricate device designs, enhancing mechanical flexibility and overall performance.

The electroluminescent film 102 may include a bottom substrate layer 104, a bottom electrode layer 106, a dielectric layer 108, an electroluminescent (EL) layer 110 which illuminates in response to an electric field, a top electrode layer 112, and a top substrate layer 114.

The bottom substrate layer 104 may be an encapsulation layer and include a elastomeric polymer. The bottom substrate layer 104 lies beneath the bottom electrode layer 106 and provides foundational mechanical support and environmental protection for the overlying functional layers. In some examples, it may be printed directly onto a glass substrate treated with octadecyltrichlorosilane (OTS) aqueous solution (0.1 v/v %) to enhance adhesion and surface compatibility. After deposition, the bottom substrate layer 104 may cured. In various experimentation, the bottom substrate layer 104 was cured at, for example, 60° C. for one hour to ensure structural integrity and uniformity.

The bottom electrode layer 106 is positioned between the bottom substrate layer 104 and the dielectric layer 108. The bottom electrode layer 106 provides a conductive and stretchable electrode, allowing electrical connectivity while maintaining mechanical flexibility. It plays a critical role in enabling alternating current activation of the EL layer 110 while supporting the mechanical integrity of the multilayer structure.

The bottom electrode layer 106 may include a mixture of a conductive filler and an elastomeric polymer. The conductive filler be a substance that is metal, carbon, and/or polymer-based. For example, the bottom electrode layer 106 may include a composite slurry of silver flakes (Ag) and the elastomeric polymer. This layer is printed directly onto the bottom substrate layer 104 using the dispenser system 100. Using a dispenser system, such as the Nordson EFD Pro 4, enables precise deposition without the need for masks or photolithography.

In some examples, a slurry is prepared by dissolving TPU pellets in a solvent mixture of tetrahydrofuran and N,N′-dimethylformamide, followed by the addition of silver flakes. The mixture may be homogenized using a planetary centrifugal mixer at, for example, 2,000 rpm for 5 minutes. Once printed, the bottom electrode layer may cured at, for example, 60° C. for one hour. In various experimentation, the bottom electrode layer exhibited excellent durability under mechanical strain, maintaining stable resistance over 10,000 stretching cycles at 20% tensile strain.

The dielectric layer 108 may include a mixture of a dielectric with the elastomeric polymer. For example, the dielectric layer may include a high-permittivity dielectric material. Accordingly the dielectric layer may include, for example, a mixture of barium titanate (BaTiO₃) and TPU. This layer may be printed using a direct-write technique that enables precise deposition without the need for masks or photolithography, contributing to the overall flexibility and manufacturability of the device. Functionally, the dielectric layer 108 serves to modulate the electric field distribution across the EL layer 110. Its high dielectric constant focuses the electric field onto the electroluminescent ZnS particles, enhancing charge separation and thereby increasing light emission. Although not strictly necessary to prevent short circuits in fully encapsulated devices, the dielectric layer 108 is important in patterned structures to avoid electrical shorting.

In various experimentation, the optimal thickness of the dielectric layer 108 was determined to be 10 μm, balancing electrical performance and mechanical flexibility. Depending on the design constraints, the thickness of the dielectric layer 108 may be varied, and acceptable performance is possible in a thickness range of 10 μm to 40 μm. Experimental data show that increasing the thickness of the BaTiO₃ leads to a reduction in electroluminescent brightness due to diminished field strength across the EL layer 110. Accordingly, the thickness of the dielectric layer may be varied across the film in order to vary at various locations on the film.

In some examples, the dielectric layer 108 may be formed with a BaTiO₃/TPU slurry prepared by dissolving TPU pellets in a solvent mixture of tetrahydrofuran and N,N′-dimethylformamide, followed by the addition of BaTiO₃ particles in varying weight ratios. The mixture is homogenized using a planetary centrifugal mixer at 2,000 rpm for 5 minutes. A 3:1 weight ratio of BaTiO₃ to TPU was found to be optimal for maximizing EL intensity without compromising printability. Once printed, the dielectric layer may be cured at 60° C. for one hour. It is positioned between the bottom electrode layer and the electroluminescent layer, forming a critical part of the multilayer structure that enables alternating current activation of the film.

The EL layer 110 may include at least one phosphorescent particle embedded in the elastomeric polymer. Upon application of AC voltage, hot carriers are injected into the phosphors, accelerating under the electric field and undergoing impact ionization. This results in radiative relaxation of luminescent centers, producing visible light. The EL layer 110 may be positioned between the dielectric layer 108 and top electrode layer 112, forming the active light-emitting region of the multilayer structure of the film 102.

The type and/or concentration of dopant used may result in a different color achieved when exposed to an electric field. It should be appreciated that the EL layer 110 may include a plurality of phosphors used on different areas or portions of the EL layer 110, thereby producing multiple colors. In some examples, the phosphors may be arranged in a grid and provide pixels where each pixel has respective phosphors for red, green, and blue.

This EL layer 110 may be fabricated using a direct-write printing technique that enables precise, mask-free deposition of functional materials, thereby simplifying the manufacturing process and enhancing design flexibility. In some examples, the phosphorescent may include zinc sulfide (ZnS) and a dopant. For example, the ZnS may be doped with various elements to achieve multicolor emission: copper (˜0.1 wt %) for blue, copper (˜0.01 wt %) for green, and manganese (˜1 wt %) for orange. These dopants determine the emission wavelength upon activation by alternating current (AC) voltage.

In an example, the EL layer 110 may be prepared for printing by dissolving TPU pellets in a solvent mixture of tetrahydrofuran and N,N′-dimethylformamide, followed by the addition of ZnS phosphors in weight ratios ranging from 1:1 to 3:1 (ZnS:TPU). A 2:1 weight ratio is selected as optimal, balancing high illuminance with printability. Higher ratios lead to excessive viscosity and particle aggregation, which hinder consistent printing and reduce light emission.

In various experimentation, the optimal thickness of the EL layer 110 was determined to be 30 μm, though the thickness may be varied with good results between 30 μm and 45 μm. Increased thickness reduces brightness due to diminished electric field strength across the layer. Mechanically, the EL layer exhibited excellent durability, maintaining over 80% of its original luminance after 10,000 cycles of folding and stretching at 20% tensile strain. It can withstand elongation up to 180% of its original length without significant performance degradation.

The top electrode layer 112 may include transparent or semitransparent flexible conductive medium. For example, the top electrode layer 112 may include a conductive hydrogel, ionogel, and/or other composite formulated to provide a transparent, stretchable, and electrically conductive interface. The EL layer 110 may be positioned between the top electrode layer 112 and the bottom electrode layer 106. The top electrode layer 112 and bottom electrode layer 106 may together provide an electric field for alternating current (AC) activation of the EL layer 110.

In various experimentation, hydrogel for the top electrode layer may be synthesized by dissolving 1 g of polyvinyl alcohol (PVA) and 0.1 g of polyethylene oxide (PEO) in 10 mL of deionized water, followed by magnetic stirring at 170° C. for 30 minutes. After cooling to ambient temperature overnight, 1 mL of a 4 g/6 mL aqueous lithium chloride (LiCl) solution is added to enhance ionic conductivity.

The hydrogel may be deposited using a direct-write dispenser system equipped with a 250 μm nozzle, and cured at room temperature. The resulting top electrode exhibits, according to various experimentation, high ionic conductivity, low charge transfer resistance, and optical transparency exceeding 80% across the visible spectrum (400-800 nm), ensuring minimal attenuation of emitted light from the underlying electroluminescent layer. Mechanically, the hydrogel maintains stable resistance over 10,000 stretching cycles at 20% tensile strain, and supports device elongation up to 180% without significant degradation. Its low elastic modulus (<15% of adjacent layers) allows for strain accommodation, preserving interfacial integrity during deformation.

The top encapsulation layer 114 may include a transparent, flexible, and stretchable material designed to protect the underlying layers of the film 102 while preserving its optical and mechanical performance. For example, the top encapsulation layer 114 may be a protective barrier against environmental factors such as moisture, dust, and mechanical abrasion. It also contributes to the overall mechanical flexibility of the device, supporting deformation modes including bending, twisting, and stretching. The top encapsulation layer 114 may be positioned above the top electrode layer (conductive hydrogel), completing the six-layer structure of the printed film. Its inclusion ensures long-term durability and performance stability of the device under repeated mechanical stress and environmental exposure.

The top encapsulation layer 114 may be a elastomeric material, such as Clear Flex. In various experimentation, Clear Flex was prepared by mixing part A and part B in a 1:1 weight ratio, and the resulting solution is printed using a 250 μm nozzle and cured at room temperature overnight. This process ensures uniform coverage and integration with the multilayer structure of the device. The resulting encapsulation layer maintained high optical transparency (>98% transmittance from 400 to 800 nm), ensuring minimal attenuation of electroluminescent output. Clear Flex using a direct-write printing technique, which enables precise deposition without the need for masks or photolithography.

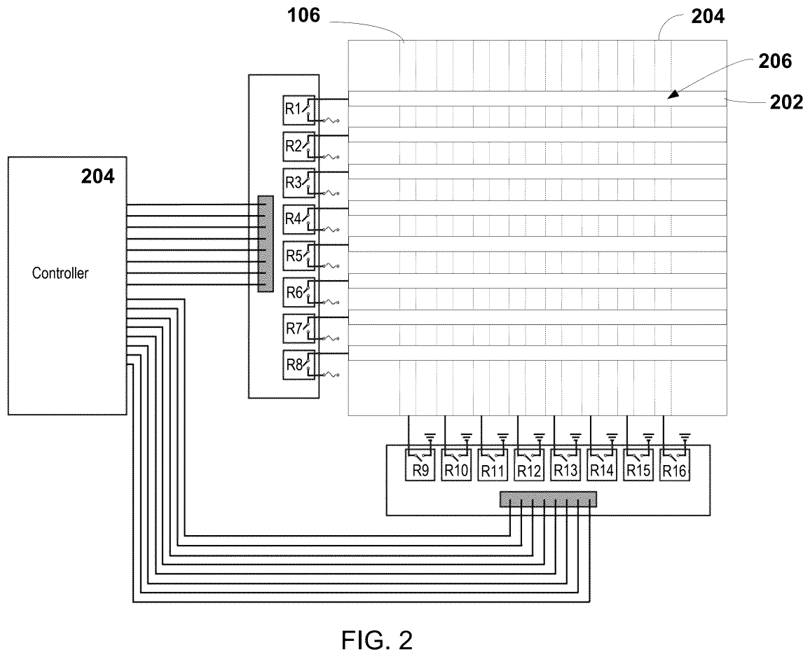

FIG. 2 illustrates an example of an electroluminescent device providing a multiplexed display. The device 100 may include the film 102. To provide a multiplexed display, the top electrode layer and bottom electrode layer may include conductive traces arranged as rows and columns in each layer respectively. For example, the top electrode layer may include conductive rows 202 and the bottom electrode layer may include a conductive column 204. The rows and columns may intersect at pixels 206. Thus, the film may be designed to provide passive matrix electronic addressing to control light emission from. The example shown in FIG. 2 includes 64 pixels, though additional or fewer pixels are possible.

The electric field present at each pixel may be selectively activated or deactivated. By way of example, the electroluminescent device may include relays R1-R16 arranged in rows and columns. The row relays R1-R8 may be connected to an alternating current source and the rows of the top electrode layer. The column relays R9-R16 may be connected to ground and the bottom electrode columns. The corresponding for each pixel may be selectively closed to activate the electric field at targeted pixel locations, thereby inducing the electroluminescent effect in the EL layer 110. This technique allows for control of an m×n matrix with only m+n control inputs, enabling operation of all 64 pixels with just 16 relays in the example shown in FIG. 2.

A controller 204 may control operation of the relays. For example, the controller may cause the relays to open and/or close. The controller may include a hardware processor, hardware memory, or a combination thereof. The controller may include an integrated circuit device configured to execute programmed instructions for controlling electronic components within a system. The controller may be operatively connected to a set of relays and is programmed to selectively activate pixel elements by managing voltage, frequency, and waveform parameters. The MCU facilitates dynamic display functionality, including pixel sweeping and alphanumeric rendering, by coordinating signal routing through m+n control lines in an m×n matrix configuration.

The passive matrix addressing allows the film to display more complex designs, such as sweeping pixel patterns and alphanumeric characters. Occasionally, unwanted pixels may activate due to the ghosting effect, which reduces pixel contrast. However, this can be mitigated by using a circuit driver that controls voltage, frequency, and waveforms, ensuring high contrast in the EL pixels. These demonstrations illustrate the versatility of the film in displaying both intricate designs and simple alphanumeric characters. The ability to create clear, detailed patterns on an n×m matrix underscores its applications in areas such as signage, displays, and custom luminescent designs.

The columns of the bottom electrode layer may be defined during printing of the layer. The columns may be conductively isolated from each other. Alternatively, the tool paths of the columns may provide minimal contact between the columns, resulting in low conductivity between columns. By way of example, the top electrode layer may be printed with alternating strips of the elastomeric polymer and a mixture of the elastomeric polymer and a conductive material to form the conductive traces which constitute the columns. Alternatively, the space between the rows may be left open without filler to isolate each column or to minimize contact between each column. The elastomeric polymer/conductive mixture may be printed on top of the bottom substrate layer, or another layer of the elastomeric polymer, to form the conductive traces.

The rows of the top electrode layer may be formed by printing strips of a flexible conductive medium. The conductive rows may be spaced to keep the rows conductively isolated from each other. Alternatively, the tool paths of the rows may minimize contact between rows, resulting in low conductivity between rows.

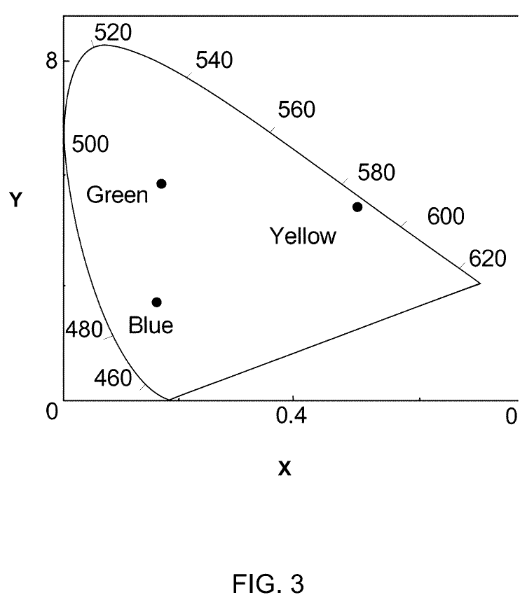

FIG. 3 presents the chromaticity coordinates of the blue (0.16, 0.45), green (0.15, 0.23), and orange (0.54, 0.43) emissions according to the CIE 1931 standard color-matching system. The blue chromaticity results where achieved by doping ZnS with Cu (˜0.1 wt %). The green chromaticity was achieved by doping ZnS with Cu (˜0.01 wt %). The orange chromaticity was achieved by doping ZnS with Mn (˜1 wt %). Other colors are possible with various types and concentrations of dopants.

### Viscosity and Light Emission Characteristics of the EL Layers

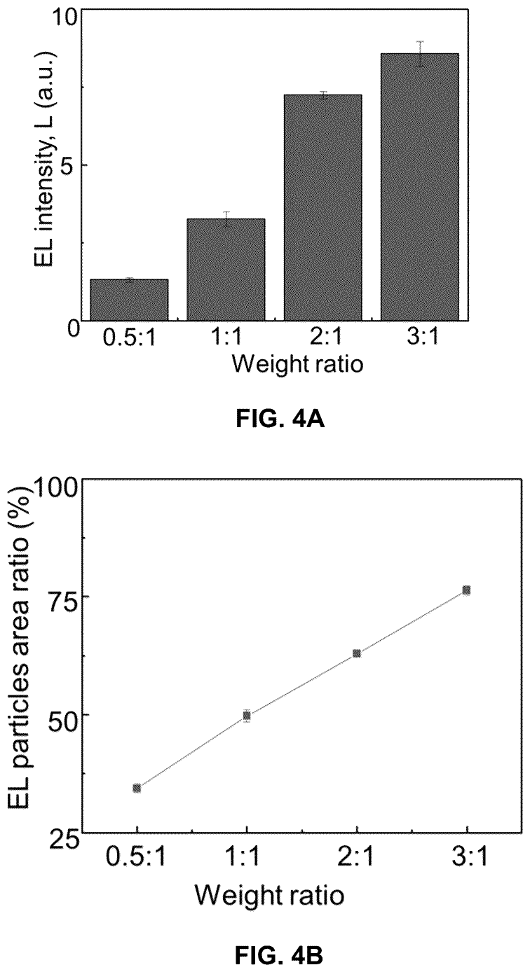

FIG. 4A illustrates the illuminance as a function of various ZnS to TPU weight ratios. FIG. 4B illustrates area percentage of ZnS phosphors and TPU. As can be seen in these figures, illuminance increases with higher ZnS content. This is because the embedded EL particles occupy a larger area within the TPU. However, when the ZnS phosphor weight ratio reaches 3:1 w/w, the EL slurry becomes too thick, hindering consistent printing, despite the higher illuminance. Excessively aggregated EL particles may block light emission, so a 2:1 w/w ratio was chosen for optimal the EL layer formulation, though a w/w ratio between 0.5:1 and 3:1 may have good results.

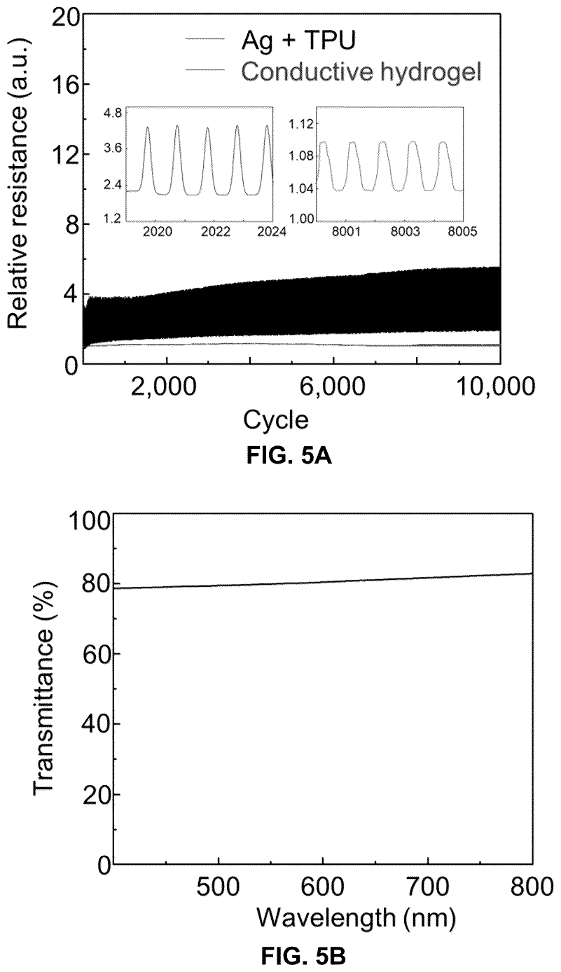

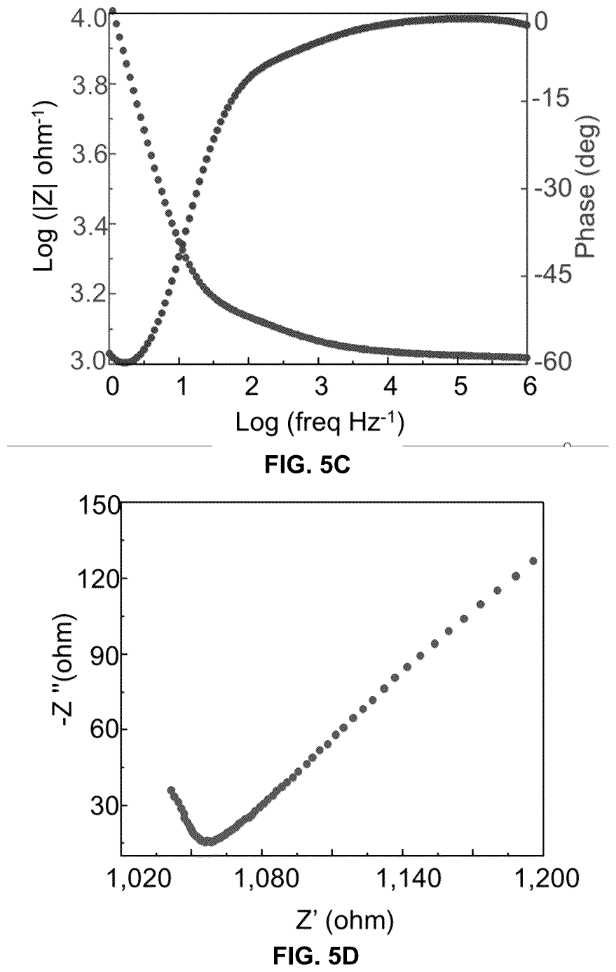

Electrical and mechanical characterization of electrode layers. FIG. 5A shows the relative resistance change of the top and bottom electrode layers during 10,000 stretching cycles at a tensile strain of 20%. Both electrodes can be regarded as resistors, with resistance typically determined by their geometric shape. According to the formula R=ρL·S⁻¹ (where R is resistance, ρ is resistivity, L is length, and S is cross-sectional area), upon stretching, the length increases and the cross-sectional area decreases, leading to an increase in resistance³³. The top and bottom electrode layers maintain excellent stability and durability under repeated mechanical strain. FIG. 5B displays the optical transmittance of the top electrode layer as a function of wavelength, showing that it maintains a high transmittance of over 80% across the visible spectrum (400 nm to 800 nm). This is further demonstrated in the inset photograph, which shows the transparency of the electrode layer placed over a university logo.

The Bode plot in FIG. 5C presents the impedance (|Z|) and phase angle of the top electrode layer. The plot illustrates that the impedance decreases with increasing frequency, indicating that the electrode becomes more conductive at higher frequencies. The phase angle shifts towards more negative values, reflecting capacitive behavior at lower frequencies and transitioning to resistive behavior at higher frequencies. This frequency-dependent electrical characteristic is typical for conductive hydrogels, which exhibit both ionic and electronic conductivity. The Nyquist plot in FIG. 5D reveals a typical semicircular pattern, characteristic of materials with both resistive and capacitive properties. The diameter of the semicircle corresponds to the charge transfer resistance, which is relatively low, indicating high ionic conductivity of the hydrogel electrode. The small diameter also confirms that the conductive hydrogel electrode maintains low resistance and reactance, making it highly suitable for applications requiring efficient charge transfer and minimal energy loss.

### Light Emission Characteristics

In a particular embodiment used during experimentation, the topmost Clear Flex layer, serves as an encapsulation layer, providing protection for the underlying functional layers. With its high optical transparency (>98% from 400 to 800 nm), the Clear Flex layer had minimal impact on the EL intensity. Below this layer is the conductive hydrogel electrode, visible as a dark layer. Next is the active EL layer, which contains phosphor particles responsible for the electroluminescent properties of the device. Beneath the active layer is a thin, white BaTiO₃ dielectric layer. Under this, a shiny grey Ag/TPU layer functions as the bottom electrode. Finally, the bottommost TPU layer acts as another encapsulating layer, completing the device's protective structure. The total thickness of the electroluminescent film is approximately 150 μm.

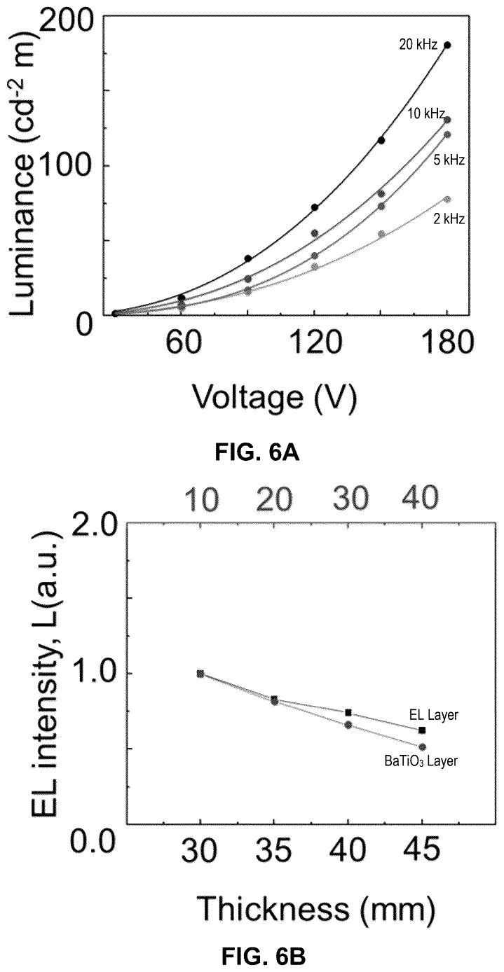

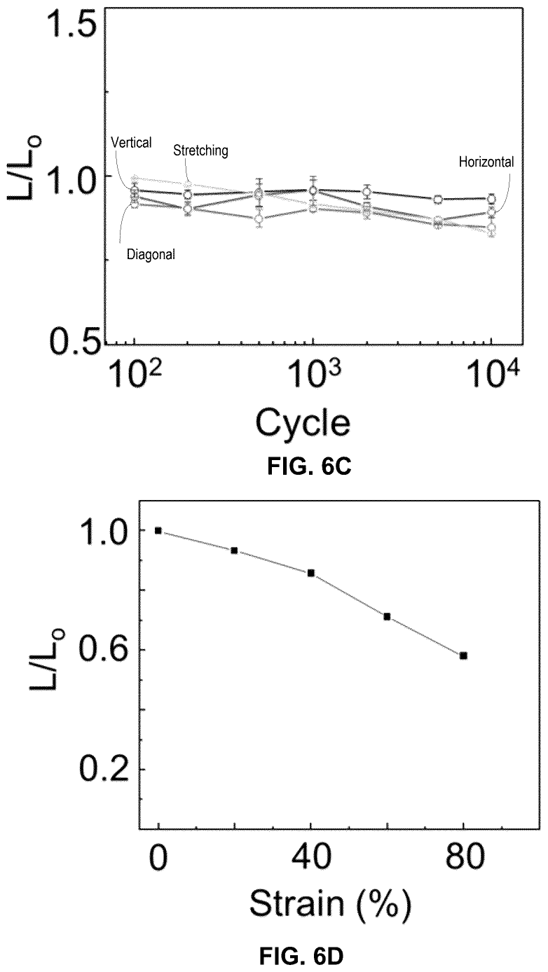

FIG. 6A demonstrates how varying the AC voltage (30 to 180 V) and frequency (2 to 20 kHz) affects EL luminance. As the frequency increases at a fixed voltage of 180 V (6 V μm⁻¹), the light emission intensity steadily rises, resulting in a luminance increase from 77.6 to 180.98 cd m⁻². Beyond a certain threshold voltage, the likelihood of electrons being accelerated to excite luminescent centers increases rapidly, causing a sharp escalation in EL intensity. The experimental data align well with the fitting curves derived from the relationship between EL luminance and the applied voltage at a given frequency, as expressed by the following equation:

$$L = {L}_{0} exp ( - \frac{β}{{V}^{1 / 2}} ) \qquad ( 1 )$$

where L represents the luminance, V represents the applied voltage, and L₀ and β are constants determined by the EL layer. FIG. 6B compares the EL intensity as a function of the thickness of both the BaTiO₃ and EL layers, showing how variations in layer thickness impact electroluminescent brightness. Both data series reveal a similar trend: increasing the thickness of either the EL or BaTiO₃ layer leads to a reduction in brightness. In the experiments, different thicknesses were achieved by adjusting the printing pressure and speed. The dependence of EL intensity on the weight ratio of BaTiO₃ to TPU indicates that EL intensity increases with higher weight ratios, reaching saturation at a 3:1 ratio. A comparison of EL intensity with and without the BaTiO₃ layer that the dielectric layer only slightly reduces EL intensity. This can be explained by the dielectric properties of the particle layer, which control the electric field distribution when voltage is applied. A matrix with a high dielectric constant focuses the electric field on the EL particles, enhancing charge separation and thus increasing light emission³⁴. While the dielectric layer is not strictly necessary to prevent short circuits—since the electrode layers do not come into direct contact in the complete film—it is required for patterned structures to avoid short circuits. To maintain consistency, we included the BaTiO₃ layer in all configurations. Based on these results, the optimal thicknesses of 30 μm for the EL layer and 10 μm for the BaTiO₃ layer were selected to maximize electroluminescent intensity.

The film demonstrated stable performance under various mechanical deformations, including twisting and bending. FIG. 6C shows relative luminance (L/L₀) vs cycles of folding in various directions. The relative luminance (L/L₀) remained above 80% after 10,000 cycles of folding in vertical, diagonal, and horizontal directions. Its response to uniaxial strain was tested by stretching the specimens until failure, with failure occurring at 180% of the original length. As the specimens were stretched, the intensity (emission/area) decreased, explaining the reduction in light emission. FIG. 6D illustrates the strain distribution along the stretching direction, revealing non-uniform deformation at the edges of the electroluminescent film due to the inhomogeneous mechanical properties of the multilayer structure. The second layer, an electrode made of conductive hydrogel, expands in a direction perpendicular to the stretching direction, while the other layers contract. Typically, materials with a positive Poisson's ratio contract perpendicularly to the stretching axis, but the electrode layer—having an elastic modulus less than 15% that of the other layers—is constrained by the contraction of the adjacent upper and lower layers. This results in the electrode layer expanding under tension, as it is strongly restricted by the adjacent nt layers, which have an elastic modulus over ten times greater. This expansion near the edges causes twisting and introduces opposite shear strain signs at the interfaces between the electrode layer and adjacent layers. In contrast, under bending or twisting deformation, the principal strain is significantly smaller than under tensile loading, and the shear strain at the edges is negligible compared to that observed under tensile deformation. This observation aligns with the intensity reduction observed exclusively under tensile strain.

Fabrication of the electroluminescent film according to an embodiment. A mixture of 6 mL tetrahydrofuran (Thermo Fisher Scientific) and 2 mL N,N′-dimethylformamide (Thermo Fisher Scientific) was used to dissolve 2 g TPU pellets (Elastollan 60A, BASF) to make the TPU solution. The TPU solution was then mixed with 8 g silver flake (Inframat Advanced Materials) to create the Ag/TPU slurry. Additionally, the TPU solution was combined with 8 g, 9 g, or 10 g BaTiO₃ (US Research Nanomaterials, Inc.) to form the BaTiO₃/TPU slurry. To prepare the EL slurry, the TPU solution was mixed with 1 g, 2 g, 4 g, or 6 g of commercially available zinc sulfide (ZnS) phosphors with different dopants (Shancghai Keyan Phosphor Technology Co.). All slurries were mixed using a planetary centrifugal mixer (ARE-310; Thinky) at 2,000 rpm for 5 minutes. To make the conductive hydrogel solution, 1 g PVA (MW˜19,500; Aldrich) and 0.1 g PEO (MW 100,000-200,000; Acros Organics) were dissolved in 10 mL deionized water and magnetically stirred at 170° C. for 30 minutes, then left at room temperature overnight. Simultaneously, 4 g LiCl (Fisher Chemical) was dissolved in 6 mL deionized water, and 1 mL of this LiCl aqueous solution was added to the PVA/PEO solution. Clear Flex (Smooth-On, Inc) solution was prepared by mixing part A and part B in a weight ratio of 1:1. All resulting slurries and solutions were then loaded into syringes with a tip diameter of 250 μm for sequential printing using a dispenser (Nordson EFD Pro 4). The glass substrate was treated with octadecyltrichlorosilane (OTS) aqueous solution at a ratio of 0.1 v/v %. After each layer was printed, it was dried in an oven at 60° C. for 1 hour before proceeding to print the next layer. The conductive hydrogel and Clear Flex layers were left at room temperature overnight. Finally, the electroluminescent film was obtained and peeled off from the glass. The viscosities of each printed material are presented in Supplementary FIG. 9.

Measurement of rheological properties according to an embodiment. The rheological properties of slurries and solutions were measured at room temperature using a rotational rheometer (Discovery HR-3, TA Instruments, USA) equipped with a 25 mm parallel plate (ETC Steel-115551). Measurements were conducted through a steady-state flow step at a shear rate ranging from 1.0 to 100 s⁻¹.

Characterizations of the electroluminescent film. Photographs and videos were captured using a digital camera (EOS 70D; Canon) equipped with an 18-135 mm lens. The surface and cross-sectional structure of the film were examined using an optical microscope (Eclipse LV150N; Nikon). The impedance of the conductive hydrogel was measured using a potentiostat (Bio-Logic SP-200). To measure the electrical properties of the conductive hydrogel and Ag/TPU under cyclic tests, a sourcemeter (Keithley 2400) and a custom-built LabView code (National Instruments) were used in a two-wire configuration. The transmittance was characterized using an ultraviolet-visible spectrophotometer (Cary 6000i UV Vis-NIR) to scan the wavelength range of 400 to 800 nm. The luminance of the light-emitting pixels was measured using a chroma meter (CS-200; Konica Minolta, Japan) under an alternating sine voltage supplied by an arbitrary waveform generator (Keithley 3390) connected to a high-voltage power amplifier (9100A-DST; Tabor Electronics). All bending, folding, and stretching tests were conducted using a mechanical testing machine (Mark-10; Willrich Precision Instruments).

Finite Element Analysis (FEA) according to an embodiment. The commercially available software ABAQUS was used to analyze the deformation behavior of the electroluminescent film. The multilayered film structure was modeled based on thicknesses measured from actual samples, with the top layers having thicknesses of 35 μm, 25 μm, 30 μm, 10 μm, 30 μm, and 20 μm, respectively. Mechanical properties were defined using a hyperelastic model, with input from uniaxial tension test data and a Poisson's ratio set to 0.45. Stretching, bending, and twisting deformations were applied by imposing displacement boundary conditions on both ends of the sample. Strain values exceeding the maximum and minimum contour limits were colored red and blue, respectively, to enhance visual analysis.

While various embodiments have been described, it will be apparent to those of ordinary skill in the art that many more embodiments and implementations are possible. Accordingly, the embodiments described herein are examples, not the only possible embodiments and implementations.

A second action may be said to be “in response to” a first action independent of whether the second action results directly or indirectly from the first action. The second action may occur at a substantially later time than the first action and still be in response to the first action. Similarly, the second action may be said to be in response to the first action even if intervening actions take place between the first action and the second action, and even if one or more of the intervening actions directly cause the second action to be performed. For example, a second action may be in response to a first action if the first action sets a flag and a third action later initiates the second action whenever the flag is set.

To clarify the use of and to hereby provide notice to the public, the phrases “at least one of <A>, <B>, . . . and <N>” or “at least one of <A>, <B>, . . . <N>, or combinations thereof” or “<A>, <B>, . . . and/or <N>” are defined by the Applicant in the broadest sense, superseding any other implied definitions hereinbefore or hereinafter unless expressly asserted by the Applicant to the contrary, to mean one or more elements selected from the group comprising A, B, . . . and N. In other words, the phrases mean any combination of one or more of the elements A, B, . . . or N including any one element alone or the one element in combination with one or more of the other elements which may also include, in combination, additional elements not listed.

What is claimed is:

1. A method, comprising:
printing a bottom substrate layer
printing a bottom electrode layer on the substrate layer;
printing a dielectric layer on the electrode layer;
printing an electroluminescent layer configured to illuminate in response to an electric field;
printing a top electrode layer comprising a flexible conductive medium, the top electrode layer configured to provide the electric field with the bottom electrode layer; and
printing a top substrate layer on the top electrode layer,
wherein the bottom substrate layer, the bottom electrode layer, the dielectric layer, and the electroluminescent layer each comprise an elastomeric polymer.

2. The method of claim 1, wherein the elastomeric polymer is thermoplastic polyurethane (TPU) and the flexible conductive medium comprises hydrogel.

3. The method of claim 1, wherein the electroluminescence layer further comprises a phosphorescent.

4. The method of claim 3, wherein the phosphorescent comprises zinc sulfide and a dopant.

5. The method of claim 1, wherein the electroluminescence layer further comprises a plurality of phosphorescents, wherein each phosphorescents are doped to achieve a different color under the electric field.

6. The method of claim 1, wherein the top electrode layer and the top substrate are transparent.

7. The method of claim 1, wherein the flexible conductive medium comprises hydrogel.

8. The method of claim 1, wherein the bottom electrode layer comprises a mixture of a conductive filler and the elastomeric polymer.

9. The method of claim 1,
wherein printing the bottom electrode layer comprises printing a plurality of conductive columns,
wherein printing the top electrode layer comprises printing a plurality of conductive rows,
wherein the conductive columns and the conductive rows together form an addressable matrix which can apply the electric field to targeted locations of the EL layer in response to an alternating current selectively applied to pairs of the conductive rows and the conductive columns.

10. The method of claim 1, wherein the dielectric layer comprises a mixture of a high-permittivity dielectric material and the elastomeric polymer.

11. The method of claim 10, wherein the high-permittivity dielectric material comprises BaTiO₃.

12. A stretchable and flexible electroluminescent film comprising:
a bottom substrate layer
a bottom electrode layer on the substrate layer;
a dielectric layer on the bottom electrode layer;
an electroluminescent layer on the dielectric layer, the electroluminescent layer configured to illuminate in response to an electric field;
a top electrode layer comprising a conductive flexible medium, the top electrode layer configured to provide the electromagnetic field with the bottom electrode layer; and
a top substrate layer on the electrode layer,
wherein the bottom substrate layer, the bottom electrode layer, the dielectric layer and the electroluminescent layer each an elastomeric polymer.

13. The stretchable and flexible electroluminescent film of claim 12, wherein the elastomeric polymer is thermoplastic polyurethane (TPU) and the flexible conductive medium comprises hydrogel.

14. The stretchable and flexible electroluminescent film of claim 12, wherein the electroluminescence layer further comprises a phosphorescent.

15. The stretchable and flexible electroluminescent film of claim 12, wherein the electroluminescence layer further comprises a plurality of phosphorescents, wherein each of the phosphorescents are doped to achieve a different color under the electric field.

16. The stretchable and flexible electroluminescent film of claim 12, wherein the top electrode layer and the top substrate layer are transparent.

17. The stretchable and flexible electroluminescent film of claim 12, wherein the top electrode layer comprises hydrogel.

18. The stretchable and flexible electroluminescent film of claim 12, wherein the bottom electrode layer comprises a mixture of conductive flakes and the elastomeric polymer.

19. The stretchable and flexible electroluminescent film of claim 12, wherein the bottom electrode layer comprises a plurality of conductive columns, wherein the top electrode layer comprises a plurality of conductive rows, wherein the conductive columns and the conductive rows together form an addressable matrix.

20. The stretchable and flexible electroluminescent film of claim 12, wherein the dielectric layer comprises barium titanate (BaTiO₃).
